(19) United States
(12) Patent Application Publication
(10) Pub. No.: US 2002/0031896 A1
(43) Pub. Date: Mar. 14, 2002

(54) Method for fabricating semiconductor device having trench isolations

(75) Inventor: Osamu Sakamoto, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 09/796,596

(22) Filed: Mar. 2, 2001

(30) Foreign Application Priority Data
Jul. 7, 2000 (JP) 2000-206299 (P)

(51) Int. Cl. H01L 21/76

(52) U.S. Cl. 438/424; 438/401

(57) ABSTRACT

The main purpose of the invention is to provide a method for fabricating a semiconductor device having trench isolations which is improved so that the transistors can be operated normally.

A resist pattern having openings for forming trenches for trench isolations in the upper part of a mark region is formed on a semiconductor wafer. By using the resist pattern as a mask, the surface of the semiconductor wafer is etched and trenches for trench isolations are formed. After removing the resist pattern an oxide film is formed on the semiconductor wafer so as to fill into the trenches for trench isolations. The oxide film is polished through chemical and mechanical polishing and, thereby, trench isolations are formed.

### BACKGROUND OF THE INVENTION

1. Field of the Invention

This invention relates, generally, to a semiconductor device having trench isolations and, more particularly, to a semiconductor device having trench isolations which are referred to as shallow trench isolations (hereinafter abbreviated as STI).

2. Description of the Background Art

FIGS. 7 to 13 are cross section views of a semiconductor device in each step of a method for fabricating for trench isolations (STI) according to a prior art. In order to clearly differentiate a “non-exposed region” from an “exposed region” in each of the drawings of FIGS. 7 to 13, FIG. 14 serves as a view which shows them two-dimensionally on a semiconductor single crystal substrate (for example, silicon wafer) 1. Cross section views in respective steps of FIGS. 7 to 13 are cross section views along the line A-B in FIG. 14. In FIG. 14 the A side shows a “non-exposed region” and the B side shows an “exposed region.”

A pad oxide film 2 is formed on the main surface of, for example, a silicon wafer 1 as shown in FIG. 7. The pad oxide film 2 is formed by oxidizing the silicon wafer 1, for example, through a thermal oxidation method.

Following this, a silicon nitride film (Si₃N₄ film) 3 is deposited on the surface of the pad oxide film 2 which is formed on the main surface of the silicon wafer 1 through, for example, an LPCVD (Low Pressure Chemical Vapor Deposition) method. This silicon nitride film 3 works as a anti-polishing layer in the later CMP (Chemical Mechanical Polishing) processing.

After that a positive resist film 4 is applied onto the entire surface of the silicon nitride film 3 formed on the main surface of the silicon wafer 1. Only the “exposed region” on the right side in FIG. 7 is covered with a mask so that the “non-exposed region” of the left side in FIG. 7 is not exposed to a light.

After that the positive resist film 4 is developed. Then the positive resist film 4 dissolves in the developing solution, without leaving any residue, from the place of the “exposed region” which is exposed to the light while the positive resist film in the place of the “exposed region” on the right side which is not exposed to the light and the positive resist film 4 in the “non-exposed region” on the left side in the figure do not dissolve in the developing solution and the positive resist film 4 remains as shown in the figure.

Here, the reason why it is necessary to provide a “non-exposed region” on the silicon wafer 1 is described.

In order to raise the production yield when producing integrated circuits, that is to say ICs, on the silicon wafer 1, it appears to be better to produce ICs on the place which is designed for the “non-exposed region.” When manufacturing ICs, however, “lot numbers” or “wafer numbers” must be etched for identifying the silicon wafers. In the case that the place for the “lot number” or the “wafer number” is used as the “exposed region” so as to be exposed to the light after the mask is put on, the pattern of the mask overlaps on the “lot number” or the “wafer number” in the region, which makes it difficult to distinguish the “lot number” or the “wafer number” with the naked eye. Therefore, the “non-exposed region” is provided in a small area on the silicon wafer 1 so that the “lot number” or the “wafer number” can be etched into the region. Here, in FIGS. 7 to 13, the “non-exposed region” is provided on the left side and the “exposed region” is provided on the right side for the convenience of the description, however, in the actual process, the “exposed region” on the right side is several multiples of ten times as broad as the “non-exposed region” in the area.

In this way, the pattern of the mask is not overlapped on the “lot number” or the “wafer number” so that the “lot number” or the “wafer number” can be read with the naked eye.

Next, as shown in FIG. 8, the silicon nitride 3, the pad oxide film 2 and the silicon wafer 1 are sequentially etched, in this order, in the place which is not covered with the positive resist film 4 by using the positive resist film 4 as an etching mask. The places where the silicon wafer 1 is etched become trenches 5 for trench isolations into which the oxide film of STI is filled. After that, the positive resist film 4, which is utilized as an etching mask, is removed.

Following this, a thick oxide film 6 is filled into the trenches 5 for trench isolations by depositing, for example, an HDP (High Density Plasma)-SiO₂ film on the entire surface of the silicon wafer 1 as shown in FIG. 9. Since there are no trenches into which the thick oxide film 6 is filled in the “non-exposed region”, the HDP-SiO₂ film remains to be deposited on the silicon nitride film 3.

Here, the CVD-SiO₂ film may be used instead of the HDP-SiO₂ film as a thick oxide film 6 filled into the trenches 5 for trench isolations.

In the process of STI, a method is adopted wherein an extra part of the thick oxide film 6 above the silicon nitride film 3 is shaved off by a well-known CMP method after the thick oxide film 6 is filled into the trenches 5 for trench isolation.

However, in the case that an extra part of the thick oxide film 6 is shaved off, by the CMP method, from the cross section structure as shown in FIG. 9, all of the thick oxide film 6 on the silicon nitride film 3 in the “non-exposed region” on the left side in the figure of the silicon wafer 1 must be shaved off. As for the thick oxide film 6 on the silicon nitride film 3 in the “non-exposed region” on the left side in the figure of the silicon wafer 1, the thick oxide film 6, of a certain film thickness, is deposited only through the HDP-SiO₂ film deposition on the silicon nitride film 3, since there are no trenches 5 for trench isolations. That is to say, a thick oxide film, of a certain film thickness, is deposited in a broad area. Here, the expression, “broad area,” is used because of the following reasons. That is to say, though the “non-exposed region” is several multiples of ten times as small as the area of the “exposed region” as described above, even this small “non-exposed region” has a large area enough to increase the variation of the polishing amount for the CMP method and, therefore, the expression of a “broad area” is, for this reason, used.

In the case that such a silicon wafer 1 is polished through the CMP method, the polishing amount of the oxide film differs greatly due to a variety of places in the silicon wafer 1, which makes larger the variation of the amount of polishing through the CMP method on the entire surface of the silicon wafer 1 and, therefore, the height of the top surface of the trench isolation 8 (see FIG. 13) from the top surface of the silicon wafer 1 differs for each trench isolation 8.

In the worst case, the height of the top surface of the trench isolation 8 becomes lower than the top surface of the silicon wafer 1. When a gate oxide film of the transistors is formed in such places and, afterwards, a polysilicon film is deposited for making gate electrodes of the transistors so as to be etched into a form of gate electrodes, the following problems arise.

That is to say, in the case that the height of the top surface of the trench isolation 8 is, for example, higher than the top surface of the silicon wafer 1 while the height of the top surface of the trench isolation 8 differs for each trench isolation 8, there are some cases wherein a residue of the polysilicon film remains at the time of etching for gate electrodes (in the case that the height of the top surface of the trench isolation 8 is high) or the gate oxide film below the polysilicon film is broken through during the etching for the gate electrodes so as to etch the silicon wafer 1 in the source or drain regions of the transistors (in the case that the height of the top surface of the trench isolation 8 is low).

The transistors of which the gate electrode is not formed as a correct structure due to the remaining residue of the polysilicon film or the transistors of which the silicon wafer 1 is etched in the drain or source region do not function correctly as a transistor, and accordingly do not make the IC function correctly.

In the case that a transistor is formed in the place where the height of the top surface of the trench isolation 8 is lower than the top surface of the silicon wafer 1, a microscopic current flows even when the voltage applied to the gate electrode is 0 (V).

An IC formed of such transistors includes a critical defect since a large amount of consumption current flows not at the time of the operation but at the time of the standby (at the time when the voltage of the gate electrode is 0 (V)) particularly in a memory IC of which the consumption power at the time of the standby must be small. Accordingly, it is necessary for the height of the top surface of the trench isolation 8 to be made the same as for respective trench isolations 8. In order to make the height of the top surface of the trench isolation 8 the same as for respective trench isolations 8, it is necessary to limit the variation of the amount of polishing by CMP to a small amount and, therefore, it becomes necessary to eliminate the place where a thick oxide film of a certain thickness, over a broad area, is deposited. That is to say, as shown in FIG. 10, it becomes necessary to etch the thick oxide film 6, which is thick, of the “non-exposed region” onto the left side of the silicon wafer, to a certain extent, by covering the part other than the “non-exposed region” on the left side of the silicon wafer 1 with a resist film 7. This way of etching of this thick oxide film 6, which is thick, to a certain extent is in general referred to as a “pre-etching” before the CMP processing.

In a prior art wherein a “non-exposed region” is formed by the mask for forming the trenches 5 for trench isolations in order to make it easy to read, with the naked eye, the “lot number” or the “wafer number,” it is always necessary to have this pre-processing, which is referred to as “pre-etching.”

Though in the prior art, the resist film 7 does not cover only the “non-exposed region” so that the “non-exposed region” is “pre-etched” as shown in FIG. 10, the “pre-etching” must also be carried out in the place of the “exposed region” since the amount of polishing through the CMP method becomes variable because of the places where an oxide film of a thick film, of a certain thickness, has been deposited in a broad area such as in a peripheral circuit part of an IC (that is to say, in a place which becomes a broad active region at the time when the STI is completed). Then, a mask becomes necessary for the “pre-etching” in the place of the “exposed region” which further increases the process steps.

Next, the resist film 7 which is employed as a mask is removed after etching the broad and thick oxide film 6, which is thick, to a certain extent through the “pre-etching” as shown in FIG. 11.

Next, after etching the broad and thick oxide film 6, which is thick and which is in the “non-exposed region” on the left side of the silicon wafer 1, to a certain extent as shown in FIG. 12, an extra part of the thick oxide film 6 is shaved off on the silicon nitride film 3 through the CMP method. The CMP method generally allows the shaving of oxide films but does not polish, or polishes only a small part, of silicon nitride films and, therefore, the height of the top surface of the silicon nitride film 3 and the height of the top surface of the trench isolation 8 become the same as shown in FIG. 12.

The remaining extra silicon nitride film 3 and the bad oxide film 2 are removed as shown in FIGS. 12 and 13 and, thereby, the trench isolations 8 are completed. Here, the removal of the silicon nitride film 3 is carried out with thermal phosphoric acid solution and the removal of the pad oxide film 2 is carried out with a hydrofluoric acid solution.

Next, the problem of the above described prior art is described.

According to the prior art, the completely “non-exposed region” must be formed without covering with the mask for forming the STI in a part of the silicon wafer in order to make it easy to distinguish, with the naked eye, the “lot number” or the “wafer number” for identifying the silicon wafer as shown in FIGS. 7 to 13.

In the case that the extra step of removing only the thick oxide film deposited on a part of the completely “non-exposed region” is not carried out, the unevenness of the amount of polishing through the CMP method becomes large for the entire silicon wafer and the height of the top surface of the trench isolation from the top surface of the silicon wafer becomes uneven so as to negatively affect the transistor characteristics. In addition, there is the problem that ICs formed of such transistors do not function properly or defects occur so as to increase the standby consumption current.

### SUMMARY OF THE INVENTION

Therefore, the purpose of this invention is to solve the above described problems, by providing a semiconductor device, having trench isolations, that is improved so that no extra step is required in order to remove the thick oxide film deposited on the completely “non-exposed region.”

Another purpose of this invention is to provide a semiconductor device, having trench isolations, which is improved so that the height of the top surface of the trench isolation from the top surface of the silicon wafer is uniform so as to be able to form proper transistors.

Still another purpose of this invention is to provide a semiconductor device, having trench isolations, which is improved so as to operate properly.

Yet another purpose of this invention is to provide a method for fabricating for such a semiconductor device having trench isolations.

A semiconductor device having trench isolations according to the first aspect of this invention comprises a semiconductor wafer. A region wherein integrated circuits are formed and a mark region wherein a mark is etched for identifying the wafer are provided on the above described semiconductor wafer. Trenches for trench isolations are provided in the above described region wherein integrated circuits are formed on the surface of the above described semiconductor wafer. Trenches for trench isolations are also formed in the above described mark region and are overlapped on the above described etched mark.

The above described mark is read out by the optical character recognition (OCR) software from the semiconductor device having trench isolations according to the second aspect of this invention.

In a semiconductor device having trench isolations according to the third aspect of this invention, an oxide film is filled into the above described trenches for trench isolations. The location of the upper surface of the above described oxide film is made higher than the position of the main surface of the above described semiconductor substrate.

In a semiconductor device having trench isolations according to the fourth aspect of this invention, the above described mark region is provided in a small area of the edge of the above described semiconductor wafer. Since the mark region is provided in a small area of the edge of the semiconductor wafer the surface of the semiconductor wafer can be utilized effectively.

In a semiconductor device having trench isolations according to the fifth aspect of this invention the height of the upper surface of the above described oxide film is made uniformly equal over the entire surface of the semiconductor wafer.

In a semiconductor device having trench isolations according to the sixth aspect of this invention, the above described mark include a lot number or a wafer number.

In a method for fabricating a semiconductor device having trench isolations according to the seventh aspect of this invention, first a photoresist is formed on the semiconductor wafer which has a mark region wherein a mark for identifying the wafer is etched and a circuit region wherein integrated circuits are formed (first step). The parts of the above described mark region and the above described circuit region of the above described photoresist are exposed to a light, which is followed by development and, thereby, a resist pattern having openings for forming trenches for trench isolations in the parts of the above described mark region and the above described circuit region is formed on the above described semiconductor wafer (second step). The surface of the above described semiconductor wafer is etched by using the above described resist pattern as a mask and, thereby, trenches for trench isolations are formed (third step). The above described resist pattern is removed (fourth step). An oxide film is formed on the above described semiconductor wafer so as to be filled into the above described trenches for trench isolations (fifth step). The above described oxide film is polished through chemical mechanical polishing and, thereby, trench isolations are formed (sixth step).

According to this invention, the mask for forming the STI is used for exposing the entire surface of the wafer. That is to say, the conventional “non-exposed region” is also exposed. Thereby, it becomes possible to eliminate a thick oxide film on the silicon nitride film, of which the film thickness is large and which occupies a broad region, and which used to have a residue in a conventional “non-exposed region.” Then, without carrying out “pre-etching,” the CMP polishing can directly be carried out.

In a method for fabricating a semiconductor device having trench isolations according to the eighth aspect of this invention the polishing of the oxide film in the above described sixth step is carried out immediately after the above described fifth step without passing through the step of etching the oxide film on the above described mark region in advance.

In a method for fabricating a semiconductor device having trench isolations according to the ninth aspect of this invention, the formation of a resist film in the above described first step is carried out after forming the pad oxide film and the silicon nitride film in sequence on the above described semiconductor wafer.

In a method for fabricating a semiconductor device having trench isolations according to the tenth aspect of this invention, the seventh step is included, after the above described sixth step, wherein the above described mark is read out by the optical character recognition software.

According to this invention the wafer is exposed by using a mask for forming the trenches for trench isolations which is overlapped on the region where a mark, such as a “lot number” or a “wafer number,” is etched for identifying the wafer. The gained semiconductor wafer has a pattern over the mark and, therefore, the mark is difficult to be distinguished with the naked eye. Such a wafer, however, can be identified when the OCR software reads out the mark.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross section view of a semiconductor device in the first step of a method for fabricating the semiconductor device according to the first embodiment;

FIG. 2 is a cross section view of a semiconductor device in the second step of a method for fabricating the semiconductor device according to the first embodiment;

FIG. 3 is a cross section view of a semiconductor device in the third step of a method for fabricating the semiconductor device according to the first embodiment;

FIG. 4 is a cross section view of a semiconductor device in the fourth step of a method for fabricating the semiconductor device according to the first embodiment;

FIG. 5 is a cross section view of a semiconductor device in the fifth step of a method for fabricating the semiconductor device according to the first embodiment;

FIG. 6 is a plan view of the semiconductor device as shown in FIG. 5;

FIG. 7 is a cross section view of a semiconductor device in the first step of a method for fabricating the semiconductor device according to a prior art;

FIG. 8 is a cross section view of a semiconductor device in the second step of a method for fabricating the semiconductor device according to a prior art;

FIG. 9 is a cross section view of a semiconductor device in the third step of a method for fabricating the semiconductor device according to a prior art;

FIG. 10 is a cross section view of a semiconductor device in the fourth step of a method for fabricating the semiconductor device according to a prior art;

FIG. 11 is a cross section view of a semiconductor device in the fifth step of a method for fabricating the semiconductor device according to a prior art;

FIG. 12 is a cross section view of a semiconductor device in the sixth step of a method for fabricating the semiconductor device according to a prior art;

FIG. 13 is a cross section view of a semiconductor device in the seventh step of a method for fabricating the semiconductor device according to a prior art;

FIG. 14 is a plan view of the semiconductor device as shown in FIG. 13.

### DESCRIPTION OF THE PREFERRED EMBODIMENTS

In the following embodiments of this invention are described in reference to the drawings.

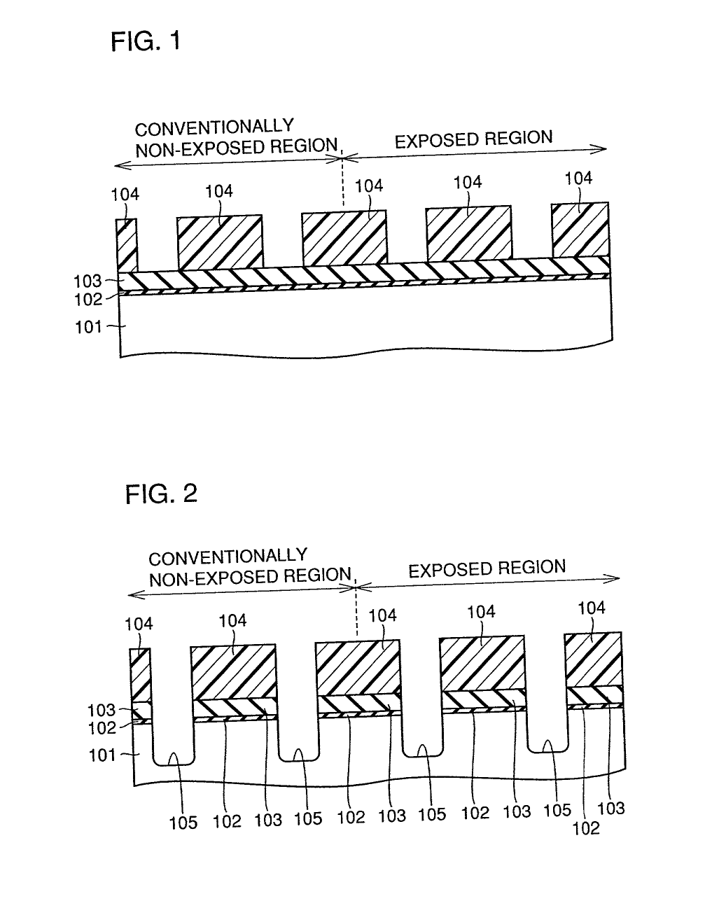

FIGS. 1 to 5 are cross section views of a semiconductor device in respective steps in the order of a method for fabricating for STI according to a embodiment of this invention. FIG. 6 is a view showing, two dimensionally on a silicon wafer 101, a distinction made between a “conventionally non-exposed region” and an “exposed region” as described in the following. A cross section view along the lines A-B in FIG. 6 corresponds to the cross section views of FIGS. 1 to 5. In FIG. 6, the B side is a “conventionally non-exposed region” on the left side in FIGS. 1 to 5 while the A side is an “exposed region” on the right side in FIGS. 1 to 5.

As shown in FIG. 1, the pad oxide film 102 is formed on the main surface of the silicon wafer 101. The pad oxide film 102 is formed, for example, by oxidizing the silicon wafer 101 through a thermal oxidation method.

Following this, a silicon nitride film 103 is deposited on the surface of the pad oxide film 102 through, for example, an LPCVD method. This silicon nitride film 103 works as an anti-polishing layer against the later CMP processing.

After that a positive resist film 104 is applied onto the entire upper surface of the silicon nitride film 103. Both the “exposed region” on the right side and the “conventionally non-exposed region” on the left side in FIG. 1 are covered with a mask so that they are irradiated with an exposure light and after that the positive resist film 104 is developed.

Then, the positive resist film 104 in the places which are irradiated with the exposure light in the “exposed region” on the right side and the “conventionally non-exposed region” on the left side in FIG. 1 is dissolved by the developing fluid so as not to remain thereon. In addition, the positive resist film 104 in the places which are not irradiated with the exposure light in the “exposed region” on the right side in FIG. 1 and the positive resist film 104 in the places which are not irradiated with the exposure light in the “conventionally non-exposed region” on the left side in FIG. 1 are not dissolved by the developing fluid so that the positive resist film 104 remains as shown in FIG. 1.

The characteristics of the present embodiment are that the “lot number” or the “wafer number” for identifying the silicon wafer 101 is already etched on the “conventionally non-exposed region” in a conventional manner before this “conventionally non-exposed region” is covered with a mask and then is exposed. Accordingly, the mask pattern is overlapped on the etched “lot number” or “wafer number” and, therefore, the “lot number” or “wafer number” is hard to be distinguished with the naked eye.

Another point should be noted here as follows.

As described in reference to FIG. 10 with respect to a prior art, in the case that, for example, there is a place where an oxide film, of which the film thickness is large, is deposited over a broad area in a peripheral circuit part, or the like, of the IC (that is to say, a place to be a broad active region at the time when the STI is completed) even in the “exposed region”, that place causes unevenness in polishing through the CMP method so that “pre-etching” becomes necessary even in the places of the “exposed region.” Then, a mask for the “pre-etching” additionally becomes necessary. Therefore, the mask for exposing the positive resist film has a “dummy pattern” so as not to have a place where an oxide film, of which the film thickness is large, is deposited over a broad area. That is to say, the mask for exposing the positive resist film is made to be such a mask as to divide the broad area for the oxide film of which the thickness is large (see FIG. 1).

Next, as shown in FIG. 2, the same step as the step shown in FIG. 8 with respect to a prior art is undertaken. That is to say, the silicon nitride film 103, the pad oxide film 102 and the silicon wafer 101 in the places which are not covered with the positive resist film 104 are etched in this order using the positive resist film 104 which has remained after the step of FIG. 1 as an etching mask.

The places where the silicon wafer 101 is etched become trenches 105 for trench isolations to which an oxide film of STI is filled in. After that, the positive resist film 104 utilized as the etching mask is removed.

Here, it should be noted that the “conventionally non-exposed region” on the left side of the silicon wafer 101 is also covered with a mask so that the positive resist film in the places which are irradiated with the exposure light is dissolved by the developing fluid and a mask pattern is copied in the same manner as in the “exposed region” on the right side of the silicon wafer 101 and, thereby, trenches 105 for trench isolations are formed.

After that, the positive resist film 104 utilized as the etching mask is removed.

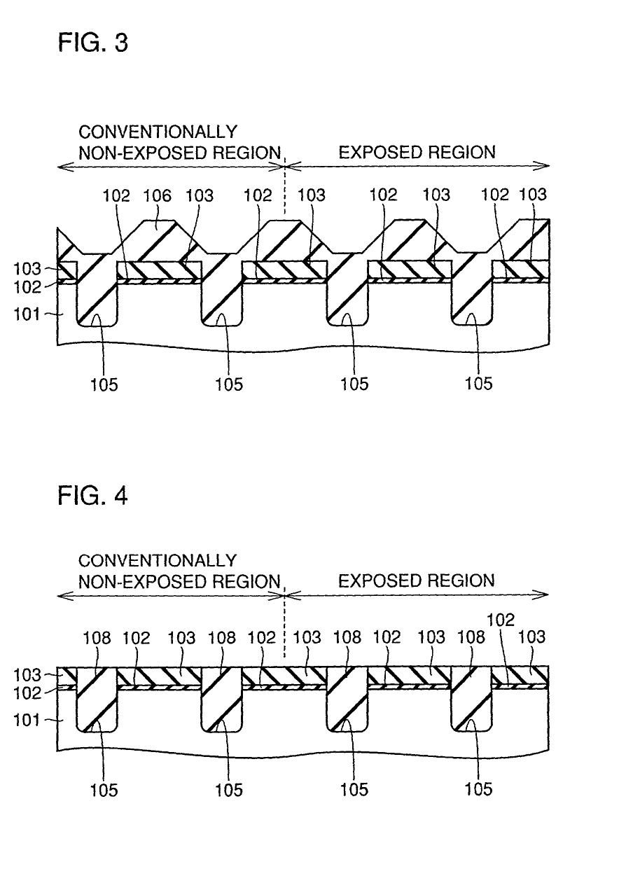

Following this, an HDP-SiO₂ film, for example, is deposited on the entire surface of the silicon wafer 101 after removing the positive resist film 104 which has become unnecessary as shown in FIG. 3, and thereby a thick oxide film 106 is filled into the trenches 105 for trench isolations. The oxide film which is filled in need not to be the HDP-SiO2 film and may, for example, be a CVD-SiO₂ film.

To be emphasized here is that trenches 105 for trench isolations are also formed in the “conventionally non-exposed region” and, therefore, an HDP-SiO2 film 106 is deposited on the “conventionally non-exposed region” on the left side of the silicon wafer 101 so as to have the same cross section structure as that of the “exposed region” on the right side of the silicon wafer 101.

That is to say, a thick oxide film 106, of which the film thickness is large, remains over a broad area on the silicon nitride film 103 in the “non-exposed region” according to a prior art and, therefore, there is a region which could increase the unevenness of polishing by CMP throughout the entire silicon wafer 101, however, in the present invention, such a region which could increase the unevenness of the polishing by CMP does not exist.

Next, the step as shown in FIG. 4 is described. A method adopted in a method for fabricating for STI is that the extra part of the thick oxide film 106 is shaved off on the silicon nitride film 103 using a well known CMP method after the thick oxide film 106 is filled into the trench 105 for trench isolations as shown in FIG. 3. In the present invention, however, a thick oxide film 106, which is thick, does not remain in the “conventionally non-exposed region” which has a broad area unlike in a prior art and, therefore, it becomes possible to omit the step of “pre-etching”, which used to be carried out in the prior art, wherein the thick oxide film 106, which is thick, in the “conventionally non-exposed region” is etched in advance to a certain extent before CMP processing. Therefore, when the structure of which the cross section view is shown in FIG. 3 is completed, the extra part of the thick oxide film 106 can be polished off directly through the CMP method without applying “pre-etching.” When the extra part of the thick oxide film 106 is polished off so as to expose the surface of the silicon nitride film 103, which is a stopper film, the polishing of the thick oxide film 106 finishes automatically so as to gain a structure as shown in FIG. 4.

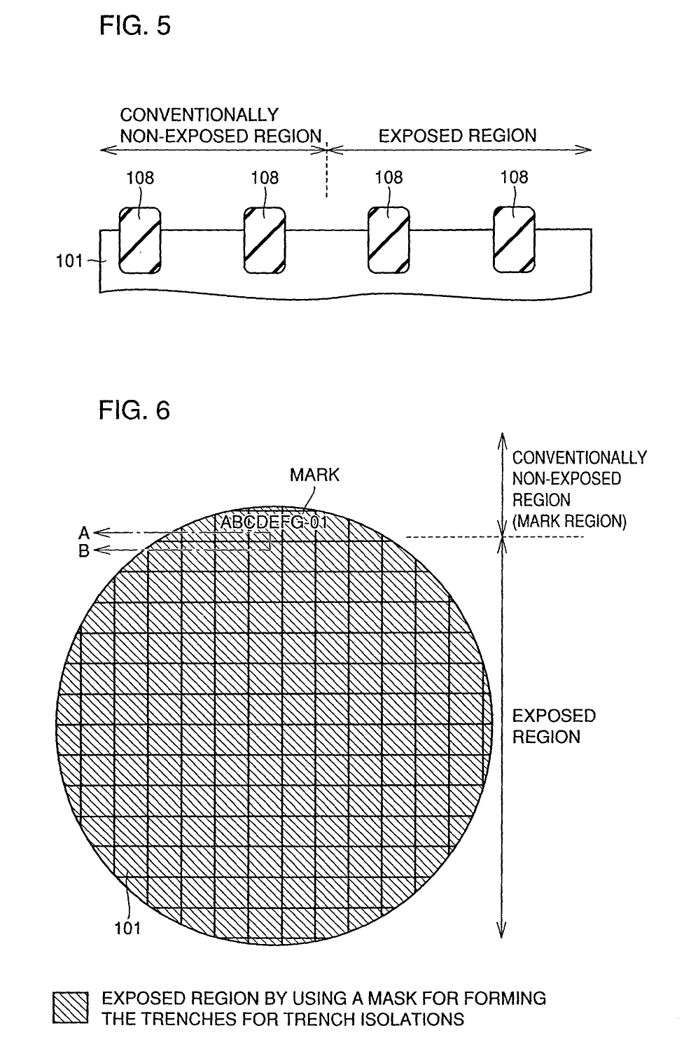

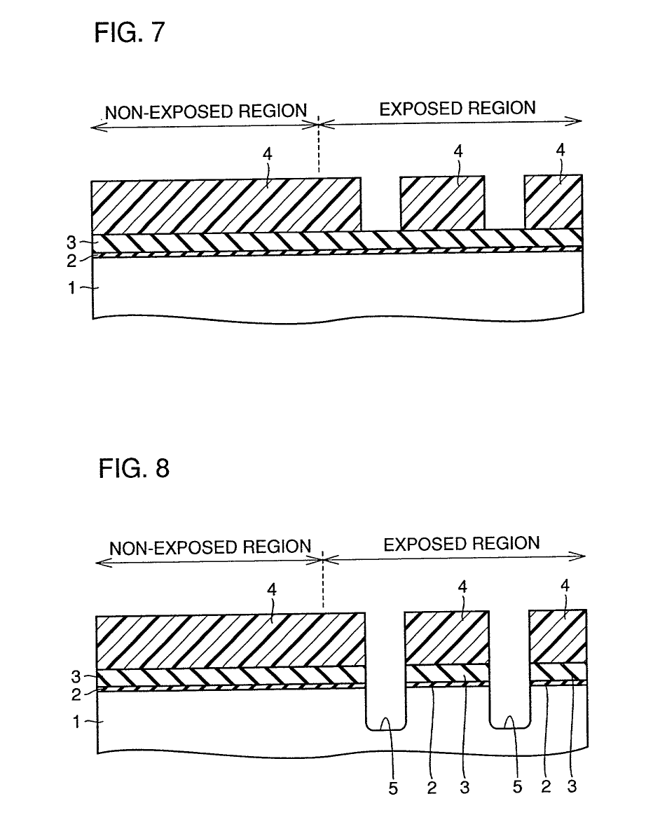

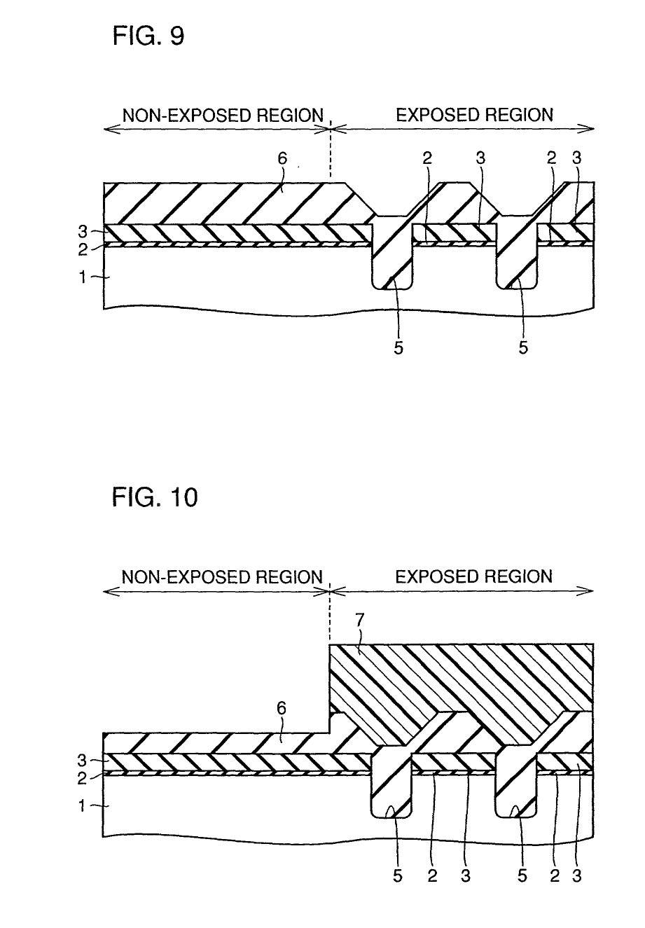

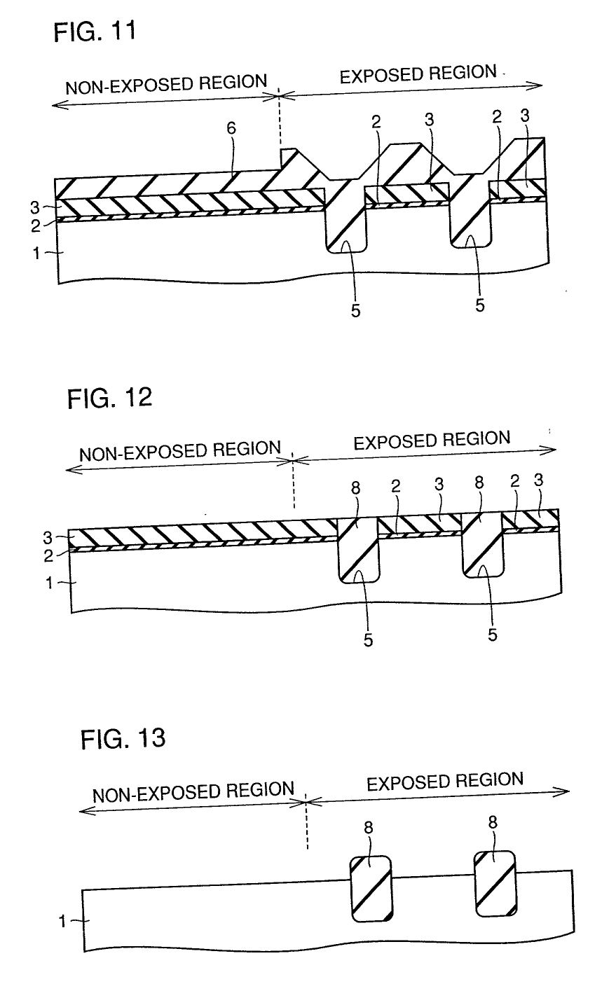

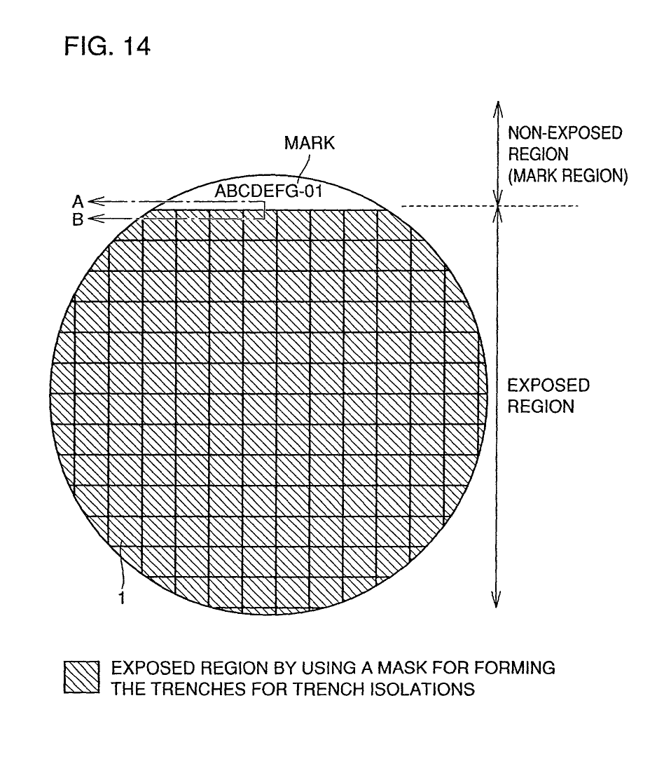

The final step is described in reference to FIG. 5. This step is exactly the same as the step shown in FIG. 13 with respect to a prior art. That is to say, the extra part of the thick oxide film 106 on the silicon nitride film 103 is shaved off through the CMP method. Next, the silicon nitride film 103 and the pad oxide film 102 are removed. Then, trench isolations 108 of which the height is uniform throughout the entire surface of the silicon wafer 101 are completed as shown in FIG. 5. Here, the silicon nitride film 103 is removed with thermal phosphoric acid solution while the pad oxide film 102 is removed with a hydrofluoric acid solution.

In this way, the mark region is covered with a mask and then the mask pattern is copied according to the present invention. After that, the silicon wafer 101 is etched, the thick oxide film 106 is deposited and trench isolations 108 are formed in the mark region. In this way, since the trench isolations are formed in the mark region according to the present invention, it is difficult to distinguish the mark with the naked eye. However, in the case that the silicon wafer 101 needs to be identified, it becomes possible to use an OCR software for distinguishing the silicon wafer 101 from other silicon wafers. Accordingly, silicon wafers can be identified in the same way as in a prior art according to the present invention.

The embodiment as disclosed herein should be considered, in all respects, as an example which is not limitative. The scope of the present invention is defined not by the above description but by the description of the claims so as to intend to include all the equivalents and modifications of the scope of the claims.

As described above, the entire surface of the wafer is exposed using a mask for forming trenches for trench isolations in order to form STI according to this invention so that the conventionally “non-exposed region” is also exposed. Thereby, the thick oxide film of which the thickness is large on the silicon nitride film and which used to remain in the conventional “non-exposed region” and which used to occupy a broad area is eliminated. Thereby, CMP processing can directly be carried out without undertaking the step of “pre-etching.” As a result, the process can be simplified by excluding the step of “pre-etching.”

In addition, the CMP processing can be prevented from becoming uneven even when the process of “pre-etching” is omitted. Accordingly, the height of the top surface of the trench isolations from the top surface of the silicon wafer becomes even throughout the entire surface of the silicon wafer so as not to have a negative effect in the characteristics of the transistors formed after the process for STI.

In addition, according to the present invention, trench isolations are formed in the region wherein the “lot number” or the “wafer number” for identifying the wafer is etched. Accordingly, it becomes difficult to distinguish the etched “lot number” or “wafer number” with the naked eye. However, when the step of reading out the etched number by the OCR software is inserted between the steps in case it becomes necessary to identify the silicon wafer, the silicon wafer can be identified in the same way as in a prior art.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method for fabricating a semiconductor device having trench isolations comprising:
the first step of formation of a photoresist on a semiconductor wafer having a mark region wherein a mark for identifying the wafer is etched and a circuit region for forming integrated circuits;
the second step of formation on said semiconductor wafer of a resist pattern having openings for forming trenches for trench isolations in said mark region and in said circuit region by exposed said mark region and said circuit region of said photoresist followed by development;
the third step of formation of said trenches for trench isolations by etching the surface of said semiconductor wafer using said resist pattern as a mask;
the fourth step of removing said resist pattern;
the five step of formation of an oxide film on said semiconductor wafer so as to fill into said trenches for trench isolations; and
the sixth step of polishing said oxide film through chemical and mechanical polishing and thereby forming trench isolations.

2. A method for fabricating a semiconductor device having trench isolations according to claim 1, wherein the polishing of the oxide film in said sixth step is carried out immediately after said fifth step without undertaking the step of etching the oxide film in said mark region in advance.

3. A method for fabricating a semiconductor device having trench isolations according to claim 1, wherein the formation of the resist film in said first step is carried out after forming the pad oxide film and a silicon nitride film in sequence on said semiconductor wafer.

4. A method for fabricating a semiconductor device having trench isolations according to claim 1, further including the seventh step of reading out said etched mark by an optical character recognition software after said sixth step.
